(19) United States
(12) Patent Application Publication
(10) Pub. No.: US 2002/0086453 A1
(43) Pub. Date: Jul. 4, 2002

(54) Method of fabricating a liquid crystal display with reduced contact resistance

(76) Inventors: Hyun Jin Kim, Kyoungki-do (KR); Ho Nyeon Lee, Kyoungki-do (KR); Jae Chul Park, Daegu (KR)

Correspondence Address: LADAS & PARRY, 224 SOUTH MICHIGAN AVENUE, SUITE 1200, CHICAGO, IL, 60604, US

(21) Appl. No.: 10/035,071

(22) Filed: Dec. 28, 2001

(30) Foreign Application Priority Data
Dec. 30, 2000 (KR) 2000-87568

(51) Int. Cl. H01L 21/00; H01L 21/3205; H01L 21/4763

(52) U.S. Cl. 438/30; 438/592

(57) ABSTRACT

A method of fabricating a liquid crystal display with reduced contact resistance is provided. The method comprises the steps of: depositing a buffer layer on a gate layer; and performing a thermal process to diffuse metal atoms of the buffer layer on the upper part of the gate, thereby forming a diffusion layer.

### BACKGROUND OF THE INVENTION 1. Field of the Invention

The present invention relates generally to a method of fabricating a liquid crystal display with reduced contact resistance and, more particularly, to a method of fabricating a liquid crystal display with reduced contact resistance by forming a buffer layer on the upper part of aluminum based metal and then, performing an annealing process.

2. Description of the Prior Art

As well known in the art, a liquid crystal display (hereinafter, referred to as LCD) is employed as information display device in information display of PDA, monitor of notebook PC and of laptop computer. Recently, it has been employed in plate monitor. In particular, the liquid crystal display has high industrial applicability as a display device alternative to a conventional Cathode Ray Tube CRT, thereby increasing the application field.

However, when single Al alloy metal is employed as a gate in the thin film transistor LCD, there is a problem that contact resistance is increased by direct contact with ITO, thereby lowering reliability of panel.

Recently, as a substrate becomes highly precise and large, Al based metal is employed as a new gate metal However, there is a severe problem that hillock generation is prevented in thermal processes and contact resistance is increased by direct contact with ITO of pixel electrode.

In order to solve the problems, a method has been proposed that a buffer layer is deposited on the Al based metal by using Mo, Cr, Ti or Ta, thereby generating hillock and prevent direct contact with ITO.

However, the method also has several problems. First, as the thickness of the buffer layer is increased, it is possible to completely prevent generation of hillock but it is difficult to control etch profile. Moreover, it is impossible to apply dry etch in forming via hole pattern, thereby applying only wet etch.

### SUMMARY OF THE INVENTION

The present invention has been proposed to solve the above-mentioned problems and an object of the present invention is to provide a method of fabricating a liquid crystal display with reduced contact resistance by forming a buffer layer on the upper part of Al based metal and retaining metal atoms thereof in annealing processes.

In order to accomplish the above object, according to the present invention, a buffer layer is deposited on a gate layer and then, a thermal process is performed to diffuse metal atoms of the buffer layer on the upper part of the gate, thereby forming a diffusion layer comprising metal atoms of buffer layer on the upper part of gate layer. Therefore, it is possible to reduce contact rate between the gate and ITO layer thereon.

It is desirable that the thermal process is performed at a temperature of 100˜450° C. for 10 mins˜5 hrs and the buffer layer has a thickness of 50˜1000 Å.

### BRIEF DESCRIPTION OF THE DRAWINGS

FIGS. 1A to 1C are drawings for showing a method of fabricating a liquid crystal display with reduced contact resistance according to an embodiment of the present invention.

FIG. 2 is a graph for showing a contact rate between gate and ITO layer to variation of sputtering time (X) according to an embodiment of the present invention.

### DETAILED DESCRIPTION OF THE INVENTION

The above objects, and other features and advantages of the present invention will become more apparent after reading the following detailed description when taken in conjunction with the appended drawings.

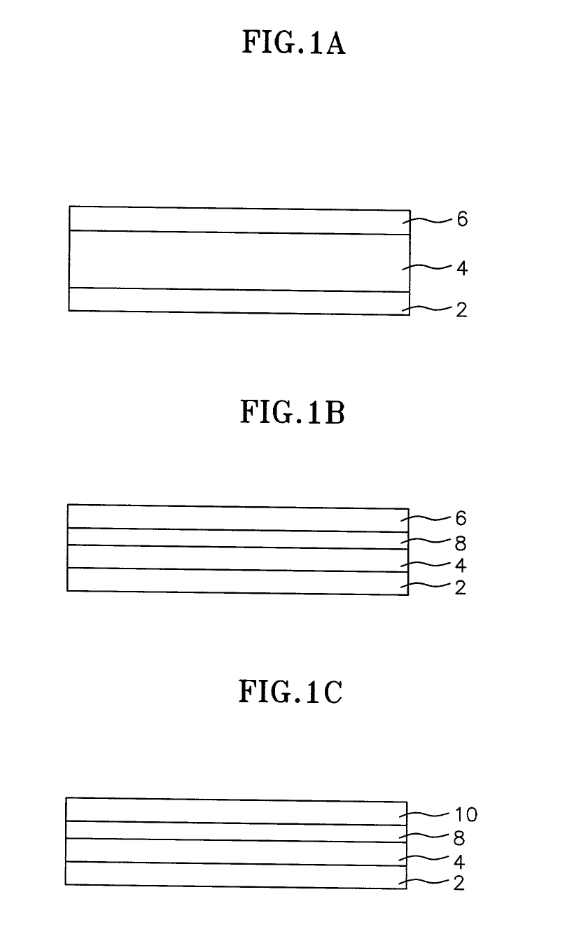

FIG. 1A to 1C are drawings for showing a method of fabricating a liquid crystal display with reduced contact resistance according to an embodiment of the present invention.

Referring to the drawings, a gate 4 made of aluminum is deposited on a glass substrate 2 and then, annealing process is performed, thereby diffusing metal atoms of the buffer layer 6, such as Mo, Cr, Ti or Ta, into the gate layer 4.

Therefore, although the buffer layer 6 is completely removed, a diffusion layer 8, comprising atoms of buffer layer 6, is retained on the surface of gate 3, thereby preventing direct contact with ITO layer 10 deposited thereon.

It is desirable that the thermal process is performed at a temperature of 100˜450° C. for 10 mins˜5 hrs to diffuse the buffer layer 6.

The buffer layer 6 has a thickness of 50˜1000 Å and it is sufficient to have a thickness of 50 Å even in dry etch of via hole.

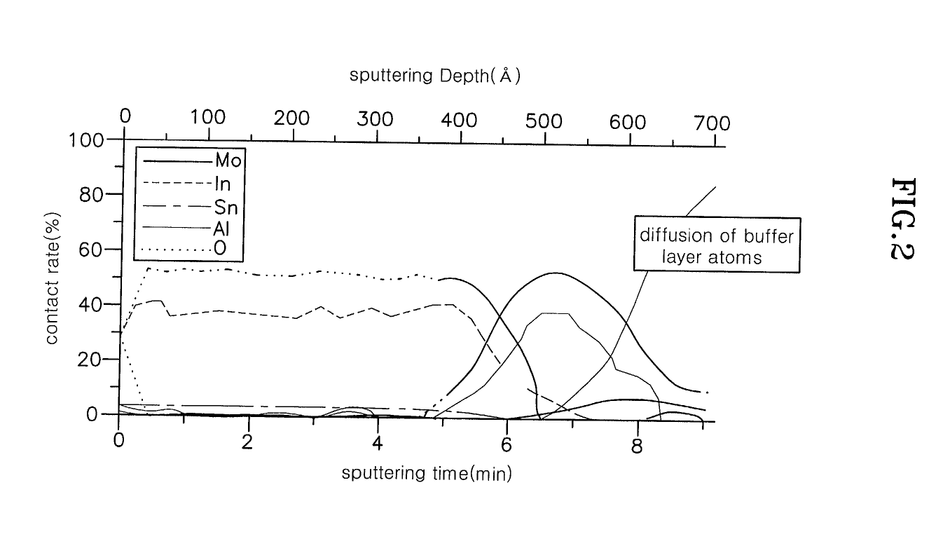

FIG. 2 shows contact rate (%) between the gate 4 and the ITO layer 10 to sputtering time X by the diffusion layer 8.

As shown in FIG. 2, a buffer layer 6 is deposited on the gate layer 4 and a thermal process is performed, thereby retaining metal atoms of the buffer layer 6 on the upper part of the gate 4 to form a diffusion layer 8. Therefore, contact rate (%) between the gate 4 and the ITO layer 10 is remarkably reduced.

And, it is possible to minimize contact resistance, thereby improving reliability of panel and having higher selectivity in employing Al alloy as a gate metal.

As described above, according to the present invention, although the buffer layer is completely removed and Al based metal is exposed, it is possible to prevent direct contact with ITO of pixel electrode, thereby obtaining stable panel and improving selectivity in etching via hole. Moreover, the present invention can solve a problem of thick buffer layer due to selectivity with insulating layer even in dry etching And, the present invention has an advantage that it becomes easy to control gate profile.

Although the preferred embodiment of this invention has been disclosed for illustrative purpose, those skilled in the art will appreciate that various modifications, alterations, additions and substitutions are possible, without departing from the scope and spirit of the invention.

What is claimed is:

1. A method of fabricating a liquid crystal display with reduced contact resistance, comprising the steps of:
depositing a buffer layer on a gate layer; and
performing a thermal process to diffuse metal atoms of the buffer layer on the upper part of the gate, thereby forming a diffusion layer.

2. The method of fabricating a liquid crystal display with reduced contact resistance according to claim 1, wherein the thermal process is performed at a temperature of 100˜450° C. for 10 mins˜5 hrs and the buffer layer has a thickness of 50˜1000 Å.
